(19) United States
(12) Patent Application Publication
(10) Pub. No.: US 2026/0011689 A1
(43) Pub. Date: Jan. 8, 2026

(54) SEMICONDUCTOR PACKAGE

(71) Applicant: SAMSUNG ELECTRONICS CO., LTD., Suwon-si (KR)

(72) Inventors: Gyuhyeong KIM, Suwon-si (KR); Junwoo PARK, Suwon-si (KR); Yongkwan LEE, Suwon-si (KR); Seunghwan KIM, Suwon-si (KR); Youngmin LEE, Suwon-si (KR); Wonhee LEE, Suwon-si (KR); Hyeon HWANG, Suwon-si (KR)

(73) Assignee: SAMSUNG ELECTRONICS CO., LTD., Suwon-si (KR)

(21) Appl. No.: 19/089,656

(22) Filed: Mar. 25, 2025

(30) Foreign Application Priority Data
Jul. 8, 2024 (KR) 10-2024-0089875

(51) Int. Cl. H01L 25/065; H01L 23/00; H01L 23/31; H01L 23/538; H10B 80/00

(52) U.S. Cl. CPC H01L 25/0655; H01L 23/3128; H01L 23/538; H01L 24/48; H01L 25/0652; H10B 80/00; H01L 24/16; H01L 24/96; H01L 24/97; H01L 2224/16227; H01L 2224/48227; H01L 2224/96; H01L 2224/97; H01L 2225/0651; H01L 2924/1436; H01L 2924/1438

(57) ABSTRACT

A semiconductor package includes: a substrate; four semiconductor chips spaced apart from each other on the substrate, each of the four semiconductor chips including an active surface that is perpendicular to an upper surface of the substrate; wires extending from the active surface of each of the four semiconductor chips, respectively, and electrically connecting the four semiconductor chips and the substrate; and an encapsulant on the substrate and surrounding the four semiconductor chips, wherein upper surfaces and first side surfaces of each of the four semiconductor chips are exposed from the encapsulant.

### CROSS-REFERENCE TO RELATED APPLICATION

This application claims the benefit under 35 USC 119(a) of Korean Patent Application No. 10-2024-0089875, filed on Jul. 8, 2024 in the Korean Intellectual Property Office, the entire disclosure of which is incorporated herein by reference for all purposes.

### BACKGROUND

Embodiments of the present disclosure relate to a semiconductor package.

As electronic devices become lighter and have higher-performance, the development of highly integrated semiconductor packages is required. Accordingly, when multiple semiconductor chips are stacked and molded within a semiconductor package, thermal resistance increases, which may cause a decrease in performance of the semiconductor chips. Accordingly, a semiconductor package technology that may effectively dissipate heat generated by semiconductor chips is required.

### SUMMARY

According to example embodiments of the present disclosure, a semiconductor package having improved heat dissipation characteristics may be provided.

According to example embodiments of the present disclosure, a semiconductor package may be provided and include: a substrate; four semiconductor chips spaced apart from each other on the substrate, each of the four semiconductor chips including an active surface that is perpendicular to an upper surface of the substrate; wires extending from the active surface of each of the four semiconductor chips, respectively, and electrically connecting the four semiconductor chips and the substrate; and an encapsulant on the substrate and surrounding the four semiconductor chips, wherein upper surfaces and first side surfaces of each of the four semiconductor chips are exposed from the encapsulant.

According to example embodiments of the present disclosure, a semiconductor package may be provided and include: a substrate; a plurality of semiconductor chip structures horizontally spaced apart from each other on the substrate; and an encapsulant on the substrate and surrounding the plurality of semiconductor chip structures, wherein upper surfaces and first side surfaces of each of the plurality of semiconductor chip structures are exposed from the encapsulant, and wherein the plurality of semiconductor chip structures and the encapsulant define a hexahedral structure on the substrate, and the first side surfaces of the plurality of semiconductor chip structures are portions of sides of the hexahedral structure.

According to example embodiments of the present disclosure, a semiconductor package may be provided and include: a substrate; four semiconductor chips horizontally spaced apart from each other on the substrate; and an encapsulant on the substrate and surrounding the four semiconductor chips, and exposing two or more surfaces of each of the four semiconductor chips, wherein at least one surface of each of the four semiconductor chips is a portion of a side surface of the semiconductor package.

### BRIEF DESCRIPTION OF DRAWINGS

The above and other aspects, features, and advantages of embodiments of the present disclosure will be more clearly understood from the following detailed description, taken in conjunction with the accompanying drawings, in which:

FIG. 1 is a schematic perspective view of a semiconductor package according to example embodiments;

FIG. 2A illustrates a plan view of the semiconductor package of FIG. 1 according to example embodiments;

FIG. 2B illustrates a cross-section along a cutting line I-I′ of FIG. 1 according to example embodiments;

FIGS. 3A and 3B are schematic perspective views illustrating a semiconductor package according to example embodiments;

FIGS. 4 to 7 are schematic perspective views illustrating a semiconductor package according to example embodiments; and

FIGS. 8A to 8E are drawings illustrating a process sequence to illustrate a method of manufacturing a semiconductor package according to example embodiments.

### DETAILED DESCRIPTION

Hereinafter, non-limiting example embodiments will be described with reference to the accompanying drawings. Hereinafter, terms such as “on,” “top,” “upper portion,” “upper surface,” “below,” “lower portion,” “lower surface,” “side,” “side surface,” and the like may be understood to refer to the drawings unless otherwise explained.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

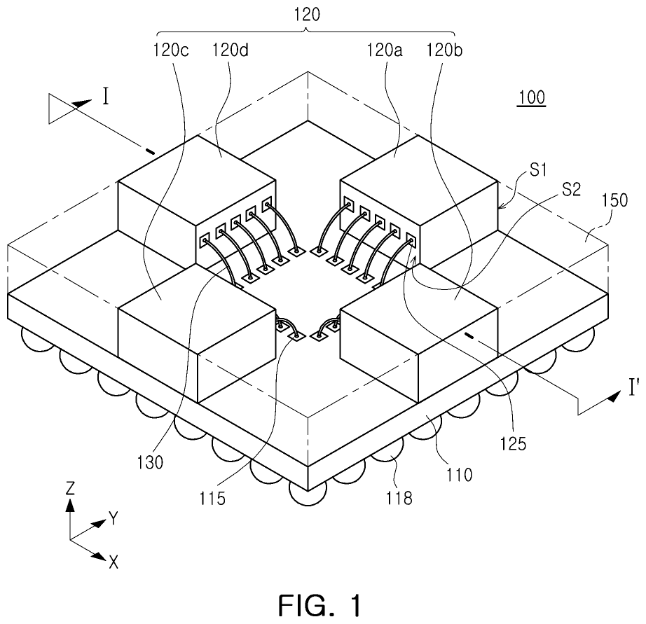

FIG. 1 is a schematic perspective view of a semiconductor package according to example embodiments.

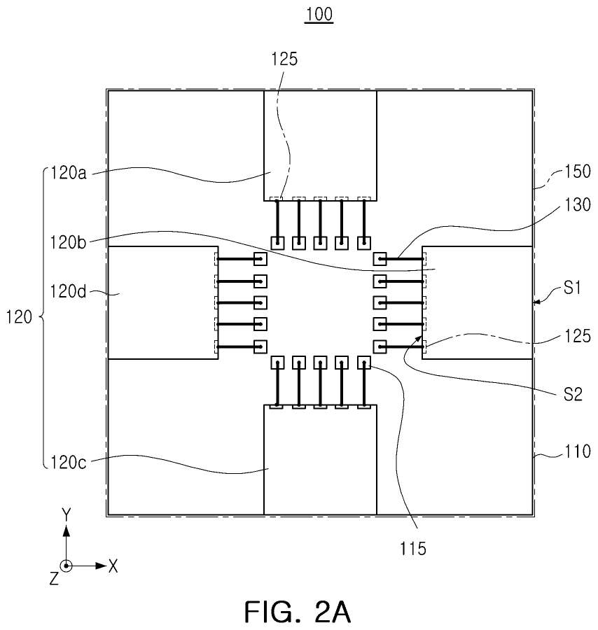

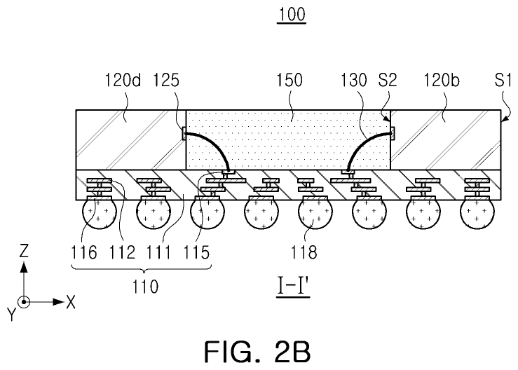

FIGS. 2A and 2B are a schematic plan view and a cross-sectional view, respectively, of a semiconductor package according to example embodiments. FIG. 2A illustrates a plan view of FIG. 1 according to example embodiments, and FIG. 2B illustrates a cross-section along a cutting line I-I′ of FIG. 1 according to example embodiments.

Referring to FIGS. 1 to 2B, a semiconductor package 100 may include a substrate 110, semiconductor chips 120 mounted on the substrate 110, wires 130 connecting the semiconductor chips 120 to the substrate 110, an encapsulant 150 surrounding (e.g., sealing) the semiconductor chips 120, and external connection bumps 118 on a lower surface of the substrate 110.

The substrate 110 may be a support substrate on which the semiconductor chips 120 are mounted, and may be a package substrate that redistributes the connection pads 125 of the semiconductor chips 120. The package substrate may include a printed circuit board (PCB), a ceramic substrate, a glass substrate, a tape interconnection substrate, or the like. The substrate 110 may include an insulating layer 111, a redistribution structure 112, upper pads 115 connected to wires 130, and lower pads 116 connected to external connection bumps 118. In example embodiments, the substrate 110 may further include a solder resist layer covering the upper pads 115 and/or the lower pads 116. In some embodiments, the substrate 110 may be an interposer substrate such as, for example, an organic interposer.

The insulating layer 111 includes an insulating material such as, for example, a thermosetting resin such as an epoxy resin or a thermoplastic resin such as a polyimide. For example, the insulating layer 111 may include a photosensitive insulating material such as a Photo Imageable Dielectric (PID) resin, a resin mixed with an inorganic filler, such as an Ajinomoto Build-up Film (ABF), a prepreg, a Flame Retardant (FR-4), or a Bismaleimide Triazine (BT). The insulating layer 111 may include a plurality of insulating layers depending on the redistribution structure 112.

The redistribution structure 112 may provide an electrical path between the upper pads 115 and the lower pads 116. The redistribution structure 112 may include interconnection layers and vias. In example embodiments, the number of layers of the interconnection layers and vias forming the redistribution structure 112 may vary.

The upper pads 115 may be exposed through the upper surface of the substrate 110 and may be electrically connected to the semiconductor chips 120 by wires 130. The upper pads 115 may be arranged in rows in a central region of the substrate 110, and the central region may be surrounded by the semiconductor chips 120 and may be an area exposed from the semiconductor chips 120. The number and arrangement of the upper pads 115 may be variously changed in example embodiments. The lower pads 116 may be exposed through the lower surface of the substrate 110 and may be connected to external connection bumps 118.

The redistribution structure 112, the upper pads 115, and the lower pads 116 may include a conductive material such as, for example, copper (Cu), aluminum (Al), silver (Ag), tin (Sn), gold (Au), nickel (Ni), lead (Pb), titanium (Ti), or alloys thereof.

The external connection bumps 118 may be disposed on the lower surface of the substrate 110 and may be electrically connected to the redistribution structure 112 through the lower pads 116. The external connection bumps 118 may physically and electrically connect the semiconductor package 100 to an external device such as a module substrate or a main board. The external connection bumps 118 may include a solder ball and/or a conductive pillar. The external connection bumps 118 may have a flip-chip connection structure having a grid array such as, for example, a pin grid array, a ball grid array, or a land grid array. The external connection bumps 118 may include, but are not limited to, a low melting point metal, such as tin (Sn), an alloy (Sn—Ag—Cu) including tin (Sn), or the like.

The semiconductor chips 120 may be mounted on the substrate 110 while being spaced apart from each other horizontally. The semiconductor chips 120 may include a plurality of semiconductor chips such as, for example, first to fourth semiconductor chips 120a, 120b, 120c and 120d. The first to fourth semiconductor chips 120a, 120b, 120c and 120d may be disposed on the upper surface of the substrate 110 on substantially the same level as each other. The semiconductor chips 120 may be attached to the substrate 110 by a separate adhesive layer, or the like. The adhesive layer may be, for example, a Die Attach Film (DAF). An upper surface and a first side surface S1 of each of the first to fourth semiconductor chips 120a, 120b, 120c and 120d may be exposed from the encapsulant 150. In this embodiment, each of the first to fourth semiconductor chips 120a, 120b, 120c and 120d may form a semiconductor chip structure.

The semiconductor chips 120 may define a hexahedral structure together with the encapsulant 150 on the substrate 110. The first side surfaces S1 of the first to fourth semiconductor chips 120a, 120b, 120c and 120d may be portions of the side surfaces of the hexahedral structure, respectively. For example, the first side surfaces S1 of the first to fourth semiconductor chips 120a, 120b, 120c and 120d may be portions of different side surfaces of the hexahedral structure.

The first side surface S1 of the first semiconductor chip 120a may be a portion of a first structure side surface of the hexahedral structure, the first side surface S1 of the second semiconductor chip 120b may be a portion of a second structure side surface of the hexahedral structure, the first side surface S1 of the third semiconductor chip 120c may be a portion of a third structure side surface of the hexahedral structure, and the first side surface S1 of the fourth semiconductor chip 120d may be a portion of a fourth structure side surface of the hexahedral structure. Since the side surfaces of the above hexahedral structure may be portions of side surfaces of the semiconductor package 100, the first side surfaces S1 may be portions of the side surfaces of the semiconductor package 100, respectively, and the relationship between the first to fourth structure side surfaces and the first side surfaces S1 may be equally applied to the relationship between the side surfaces of the semiconductor package 100 and the first side surfaces S1.

As illustrated in the plan view of FIG. 2A, the semiconductor chips 120 and the encapsulant 150 may form a quadrangular shape. In the present embodiment, the first to fourth semiconductor chips 120a, 120b, 120c and 120d may be disposed to respectively contact respective sides of the quadrangle. The first to fourth semiconductor chips 120a, 120b, 120c and 120d may be respectively disposed at the centers of respective sides of the quadrangle. The first side surfaces S1 of the first to fourth semiconductor chips 120a, 120b, 120c and 120d may be coplanar with the side surfaces of the encapsulant 150, respectively.

The first semiconductor chip 120a may be disposed to face the third semiconductor chip 120c while being spaced apart from each other on a straight line in the Y direction, and the second semiconductor chip 120b may be disposed to face the fourth semiconductor chip 120d while being spaced apart from each other on a straight line in the X direction. In example embodiments, a size of each of the first to fourth semiconductor chips 120a, 120b, 120c and 120d such as, for example, a length in the X direction and the Y direction and a height in the Z direction, may be varied.

Second side surfaces S2 opposite to the first side surfaces S1 of the semiconductor chips 120 may face the central region of the substrate 110. In each of the first to fourth semiconductor chips 120a, 120b, 120c and 120d, the second side surface S2 may be an active surface. For example, each of the first to fourth semiconductor chips 120a, 120b, 120c and 120d may include a second side surface S2 at (e.g., in or on) which connection pads 125 are disposed, and/or may include a device layer or active layer positioned adjacent to the second side surface S2 and on which an integrated circuit (IC) is disposed. The first to fourth semiconductor chips 120a, 120b, 120c and 120d may be mounted on the substrate 110 such that the second side surfaces S2, which are active surfaces, are positioned in a direction perpendicular to the upper surface of the substrate 110. The respective integrated circuits of the first to fourth semiconductor chips 120a, 120b, 120c and 120d may be electrically connected to the substrate 110 through the connection pads 125 disposed at (e.g., in or on) the second side surfaces S2.

Each of the first to fourth semiconductor chips 120a, 120b, 120c and 120d may include a memory semiconductor chip and/or a logic semiconductor chip. The memory semiconductor chip may be a volatile memory such as a dynamic random access memory (DRAM), a static random access memory (SRAM), or a nonvolatile memory such as a NAND flash memory. The logic semiconductor chip may be a microprocessor such as, for example, a central processing unit (CPU), a graphics processing unit (GPU), a field programmable gate array (FPGA), an application processor (AP), a digital signal processor, an encryption processor, a controller, or an application specific integrated circuit (ASIC). For example, each of the first to fourth semiconductor chips 120a, 120b, 120c and 120d may include a DRAM element or a NAND element.

The body portions of the semiconductor chips 120 may include silicon (Si), germanium (Ge), gallium arsenide (GaAs), silicon carbide (SiC), etc., and the connection pads 125 may include a conductive material such as tungsten (W), aluminum (Al), copper (Cu), or the like.

The connection pads 125 may be electrically connected to the redistribution structure 112 of the substrate 110 through wires 130. In the present embodiment, the connection pads 125 are disposed within the body portions of the semiconductor chips 120 such that outer surfaces of the connection pads 125 are coplanar with the second side surfaces S2 of the semiconductor chips 120, but the arrangement of the connection pads 125 is not limited thereto. In some embodiments, a passivation layer exposing the connection pads 125 may be further disposed on the second side surfaces S2 of the semiconductor chips 120. The passivation layer may include a silicon oxide and/or a silicon nitride. In example embodiments, the number and arrangement of the connection pads 125 at (e.g., in or on) the second side surfaces S2 may be varied.

The wires 130 may physically and electrically connect the connection pads 125 of the semiconductor chips 120 to the upper pads 115 of the substrate 110, thereby electrically connecting the semiconductor chips 120 and the substrate 110. The wires 130 may extend from the second side surfaces S2 of the semiconductor chips 120 to the central region of the substrate 110. Since the wires 130 extend from the second side surfaces S2 rather than the upper surfaces of the semiconductor chips 120, the upper ends of the wires 130 may be located at a lower level than a level of the upper surfaces of the semiconductor chips 120. The wires 130 may include at least one from among a conductive metal such as, for example, gold (Au), aluminum (Al), copper (Cu), or alloys thereof.

The encapsulant 150 may surround (e.g., seal) and protect the semiconductor chips 120. The encapsulant 150 may seal the semiconductor chips 120 so that the first side surfaces S1 and the upper surfaces of the semiconductor chips 120 are exposed. The side surfaces of the encapsulant 150 may be coplanar with the first side surfaces S1 of the first to fourth semiconductor chips 120a, 120b, 120c and 120d, respectively.

The encapsulant 150 may include an insulating material, and may include, for example, a thermosetting resin such as an epoxy resin, a thermoplastic resin such as a polyimide, a prepreg including an inorganic filler and/or glass fiber, ABF, FR-4, BT, Epoxy Molding Compound (EMC), or PID.

In the semiconductor package 100, since the upper surface and side surfaces of the semiconductor chips 120 are exposed from the encapsulant 150 as described above, the heat dissipation characteristics may be improved while including a plurality of semiconductor chips 120. For example, compared to a semiconductor package having a structure in which semiconductor chips 120 are vertically stacked in the Z direction, in the semiconductor package 100, as the exposed area of the semiconductor chips 120 increases, the thermal resistance may be reduced, and thus the heat dissipation characteristics may be improved. In addition, since the active layers of the semiconductor chips 120 are positioned along the second side surfaces S2, the height of the upper end of the wires 130 may be lowered, so that the wires 130 may be prevented from being exposed during the manufacturing process of the semiconductor package 100 and causing defects.

In the description of the example embodiments below, description that overlaps with the description provided above with reference to FIGS. 1 to 2B may be omitted.

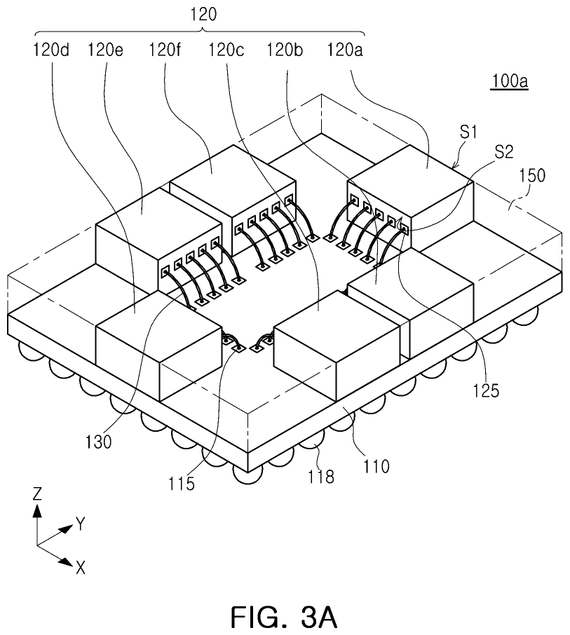

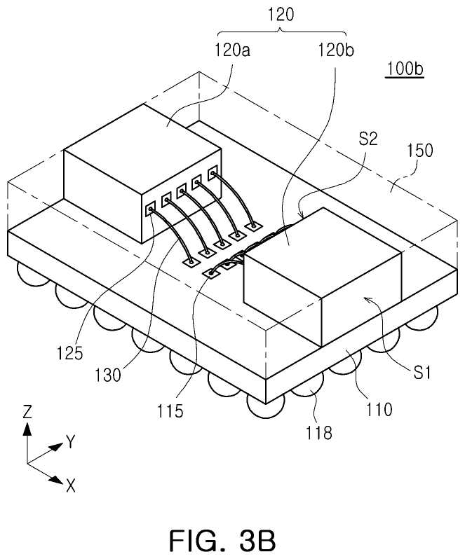

FIGS. 3A and 3B are schematic perspective views illustrating a semiconductor package according to example embodiments.

Referring to FIG. 3A, in a semiconductor package 100a, the semiconductor chips 120 may include first to sixth semiconductor chips 120a, 120b, 120c, 120d, 120e and 120f that are horizontally spaced from each other.

The first to sixth semiconductor chips 120a, 120b, 120c, 120d, 120e and 120f may be disposed on the upper surface of the substrate 110 at substantially the same level as each other. The upper surface and the first side surface S1 of each of the first to sixth semiconductor chips 120a, 120b, 120c, 120d, 120e and 120f may be exposed from the encapsulant 150.

The semiconductor chips 120 may define a hexahedral structure together with the encapsulant 150 on the substrate 110. The first side surface S1 of the first semiconductor chip 120a may be a portion the first structure side surface of the hexahedral structure and the semiconductor package 100a, the first side surfaces S1 of the second and third semiconductor chips 120b and 120c may be portions of the second structure side surface of the hexahedral structure and the semiconductor package 100a, the first side surface S1 of the fourth semiconductor chip 120d may be a portion of the third structure side surface of the hexahedral structure and the semiconductor package 100a, and the first side surfaces S1 of the fifth and sixth semiconductor chips 120e and 120f may be exposed through the fourth structure side surface of the hexahedral structure and the semiconductor package 100a.

The second side surfaces S2 opposite to the first side surfaces S1 of the semiconductor chips 120 may be disposed perpendicular to the upper surface of the substrate 110 and may face the central region of the substrate 110. In each of the first to sixth semiconductor chips 120a, 120b, 120c, 120d, 120e and 120f, the second side surface S2 may be an active surface at (e.g., in or on) which connection pads 125 are disposed.

Referring to FIG. 3B, in a semiconductor package 100b, the semiconductor chips 120 may include first and second semiconductor chips 120a and 120b that are horizontally spaced from each other.

The first and second semiconductor chips 120a and 120b may be disposed on the upper surface of the substrate 110 at substantially the same level as each other. The upper surface and the first side surface S1 of each of the first and second semiconductor chips 120a and 120b may be exposed from the encapsulant 150.

The second side surfaces S2 opposite to the first side surfaces S1 of the semiconductor chips 120 may be disposed perpendicular to the upper surface of the substrate 110 and may face the central region of the substrate 110. In each of the first and second semiconductor chips 120a and 120b, the second side surface S2 may be an active surface at (e.g., in or on) which the connection pads 125 are disposed.

As in the example embodiments of FIGS. 3a and 3b, the number of semiconductor chips 120 may be varied in the example embodiments including, for example, as a multiple of the number.

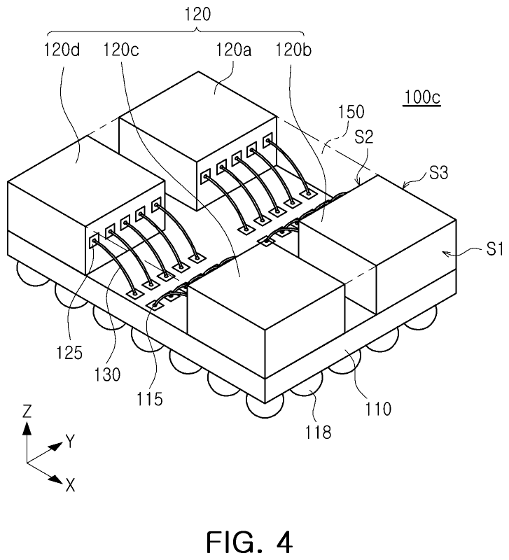

FIGS. 4 to 7 are schematic perspective views illustrating semiconductor packages according to example embodiments.

Referring to FIG. 4, in a semiconductor package 100c, the upper surface, the first side surface S1, and a third side surface S3 of each of the first to fourth semiconductor chips 120a, 120b, 120c and 120d may be exposed from the encapsulant 150. In the present embodiment, each of the first to fourth semiconductor chips 120a, 120b, 120c and 120d may have a total of three surfaces, including the upper surface, the first side surface S1, and the third side surface S3, exposed through the encapsulant 150.

The semiconductor chips 120 may define a hexahedral structure together with the encapsulant 150 on the substrate 110. The semiconductor chips 120 may be positioned at four corners of the hexahedral structure, respectively. Accordingly, two side surfaces of each of the first to fourth semiconductor chips 120a, 120b, 120c and 120d may be portions of respective side surfaces of the hexahedral structure and the semiconductor package 100c. For example, each of the first to fourth semiconductor chips 120a, 120b, 120c and 120d may have two side surfaces respectively exposed at two side surfaces of the hexahedral structure and the semiconductor package 100c.

In the present embodiment, the upper pads 115 of the substrate 110 may be arranged from each other in the Y direction between, in the X direction, the first and fourth semiconductor chips 120a and 120d and the second and third semiconductor chips 120b and 120c. However, in some embodiments, the upper pads 115 may also be arranged from each other in the X direction between, in the Y direction, the first and second semiconductor chips 120a and 120b and the third and fourth semiconductor chips 120c and 120d.

In this manner, in example embodiments, within the range of forming a hexahedral structure with the encapsulant 150, the arrangement positions of the semiconductor chips 120 may be varied, and accordingly, the number of respective surfaces the semiconductor chips 120 exposed from the encapsulant 150 may be varied within a range of two or more.

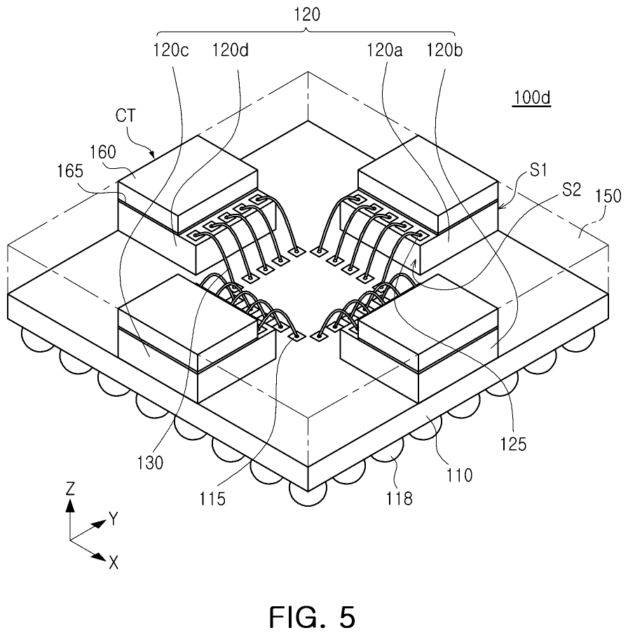

Referring to FIG. 5, a semiconductor package 100d may further include spacers 160 on the semiconductor chips 120.

The spacers 160 may be disposed on the respective upper surfaces of the first to fourth semiconductor chips 120a, 120b, 120c and 120d. The spacers 160 may radiate heat generated from the semiconductor chips 120 to the outside. The spacers 160 may include, for example, a material having a higher thermal conductivity than a thermal conductivity of the encapsulant 150. For example, the spacers 160 may include silicon (Si). The spacers 160 may also be referred to as dummy chips, heat dissipation members, or the like. The spacers 160 may be attached to the first to fourth semiconductor chips 120a, 120b, 120c and 120d by an adhesive film 165. The adhesive film 165 may be, but is not limited to, a die attach film (DAF). One spacer 160 and one semiconductor chip 120 that are vertically stacked may form one semiconductor chip structure CT. Accordingly, a plurality of semiconductor chip structures CT may be provided that respectively include one from among the first to fourth semiconductor chips 120a, 120b, 120c and 120d, and one spacer 160.

The spacers 160 may have a smaller size or smaller area on a plane than an area of each of the first to fourth semiconductor chips 120a, 120b, 120c and 120d, and may expose portions of respective upper surfaces of the first to fourth semiconductor chips 120a, 120b, 120c and 120d. For example, the spacers 160 may expose regions adjacent to the second side surfaces S2 on respective upper surfaces of the first to fourth semiconductor chips 120a, 120b, 120c and 120d. However, in some embodiments, the spacers 160 may not expose the upper surfaces of the first to fourth semiconductor chips 120a, 120b, 120c and 120d and may have substantially the same size as a size of the first to fourth semiconductor chips 120a, 120b, 120c and 120d on a plane.

The connection pads 125 may be disposed on the upper surfaces of the semiconductor chips 120 exposed from the spacers 160. The wires 130 may extend from the upper surfaces of the semiconductor chips 120 to the substrate 110. In the present embodiment, the active surface adjacent to the active layer of each of the first to fourth semiconductor chips 120a, 120b, 120c and 120d may be the upper surface or the second side surface S2. However, in some embodiments, the connection pads 125 may be located on the second side surfaces S2 as in the example embodiment of FIG. 1.

The encapsulant 150 may expose the upper surfaces and one side surface of each of the semiconductor chip structures CT. In detail, the encapsulant 150 may expose the upper surfaces and one side surface of the spacers 160 and expose the first side surfaces S1 of the semiconductor chips 120. The one side surface of the spacers 160 exposed by the encapsulant 150 may be coplanar with the first side surfaces S1 of the semiconductor chips 120.

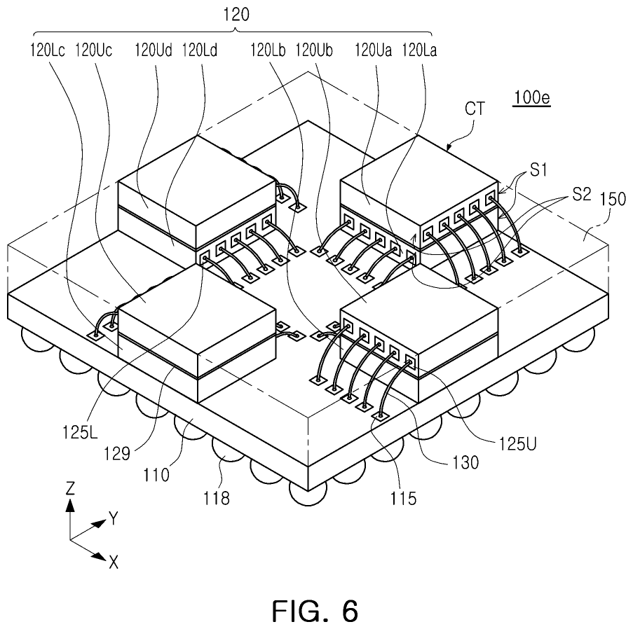

Referring to FIG. 6, the semiconductor chips 120 of a semiconductor package 100e may include first to fourth lower semiconductor chips 120La, 120Lb, 120Lc and 120Ld and first to fourth upper semiconductor chips 120Ua, 120Ub, 120Uc and 120Ud. The first to fourth lower semiconductor chips 120La, 120Lb, 120Lc and 120Ld and the first to fourth upper semiconductor chips 120Ua, 120Ub, 120Uc and 120Ud that are stacked vertically on each other may respectively form a semiconductor chip structure CT.

The first to fourth lower semiconductor chips 120La, 120Lb, 120Lc and 120Ld may have second side surfaces S2 as active surfaces. Accordingly, the wires 130 may electrically connect lower connection pads 125L on the second side surfaces S2 and the upper pads 115 of the central region of the substrate 110 in a similar form to the example embodiment of FIG. 1.

Each of the first to fourth upper semiconductor chips 120Ua, 120Ub, 120Uc and 120Ud may have a side surface connecting the first side surface S1 and the second side surface S2, and this side surface may be an active surface. The wires 130 may electrically connect upper connection pads 125U of the side surfaces and the upper pads 115 of a corner region of the substrate 110. However, in some embodiments, the first to fourth upper semiconductor chips 120Ua, 120Ub, 120Uc and 120Ud may also have second side surfaces S2 as active surfaces, and upper connection pads 125U may be disposed at (e.g., in or on) the second side surfaces S2 and may be connected to upper pads 115 in the central region of the substrate 110 by wires 130.

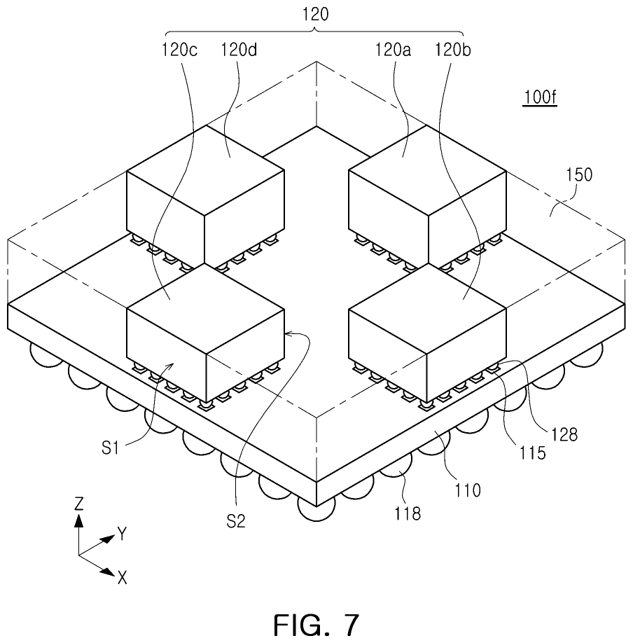

Referring to FIG. 7, a semiconductor package 100f may include connection bumps 128 instead of the wires 130 of FIG. 1.

The connection bumps 128 may be disposed on respective lower surfaces of the semiconductor chips 120 to electrically connect the semiconductor chips 120 and the substrate 110. The connection bumps 128 may connect the connection pads on the lower surfaces of the semiconductor chips 120 to the upper pads 115 of the substrate 110. The connection bumps 128 may include at least one from among tin (Sn), indium (In), bismuth (Bi), antimony (Sb), copper (Cu), silver (Ag), zinc (Zn), lead (Pb), or alloys thereof, such as Sn—Ag—Cu. For example, the connection bumps 128 may be micro bumps in which a metal pillar and a solder ball are combined.

In some embodiments, the semiconductor package 100f may further include an underfill layer surrounding the connection bumps 128 between the semiconductor chip 120 and the substrate 110. The underfill layer may include an insulating material, such as an epoxy resin. The underfill layer may have, for example, a Capillary UnderFill (CUF) structure, but is not limited thereto. In some embodiments, the underfill layer may have a Molded UnderFill (MUF) structure integrated with the encapsulant 150.

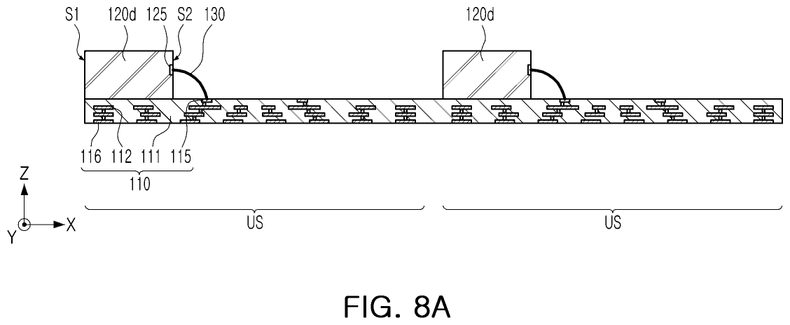

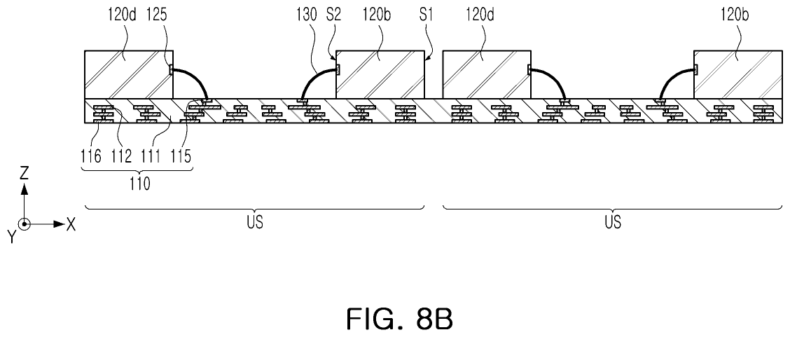

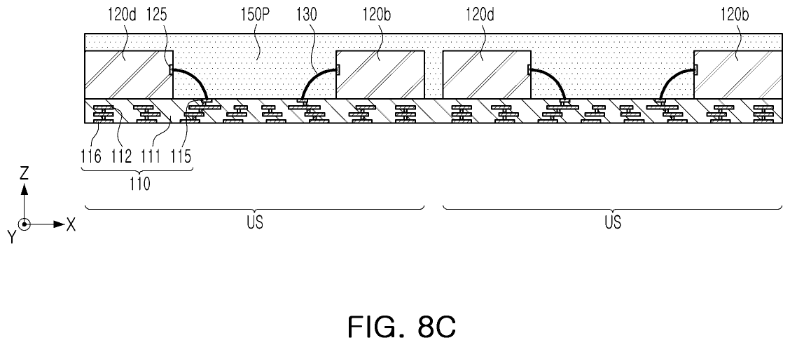

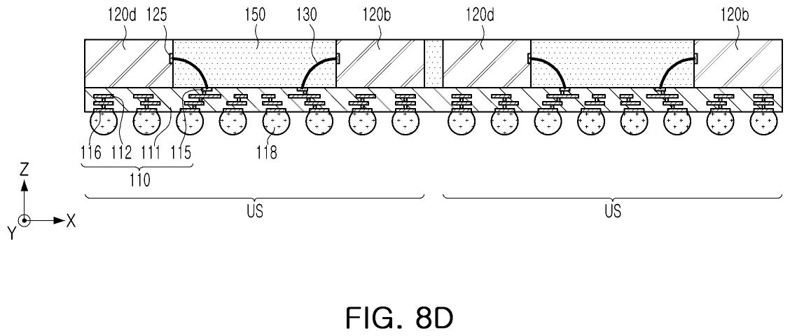

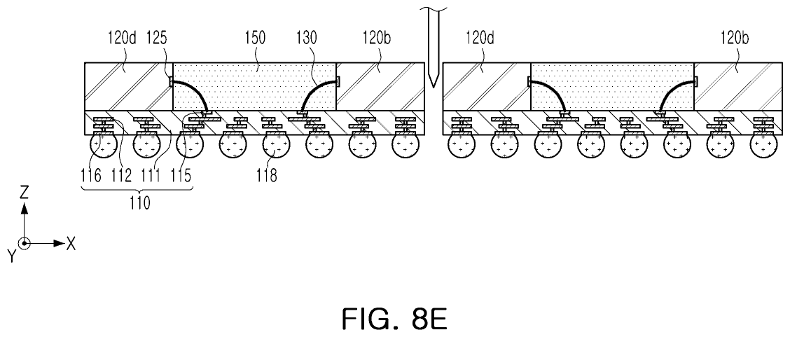

FIGS. 8A to 8E are drawings illustrating a manufacturing method of a semiconductor package according to example embodiments according to a process sequence. FIGS. 8A to 8E illustrate an example embodiment of a manufacturing method for manufacturing a power semiconductor device of FIGS. 1 to 2B, and respectively illustrates areas corresponding to FIG. 2B.

Referring to FIG. 8A, a substrate 110 may be prepared, and fourth semiconductor chips 120d may be mounted on the substrate 110.

The substrate 110 may be a strip substrate or a wafer substrate including unit substrate areas US. The substrate 110 may be temporarily supported by a separate carrier substrate, or the like. The carrier substrate may include, for example, a glass wafer, a curable resin layer, or the like.

In this operation, some of the semiconductor chips 120 may be mounted on the substrate 110 and, for example, the fourth semiconductor chips 120d may be mounted. The fourth semiconductor chips 120d may have connection pads 125 disposed at (e.g., in or on) the second side surfaces S2, and may be connected to the substrate 110 by wires 130 connecting the connection pads 125 and the upper pads 115 of the substrate 110.

Referring to FIG. 8B, the second semiconductor chips 120b may be mounted on the substrate 110.

The second semiconductor chips 120b may be mounted so that the second side surfaces S2 thereof face the second side surfaces S2 of the fourth semiconductor chips 120d. The second semiconductor chips 120b may be connected to the substrate 110 by wires 130 connecting the connection pads 125 exposed from the second side surfaces S2 and the upper pads 115 of the substrate 110.

In the same manner, the first semiconductor chips 120a and the third semiconductor chips 120c of FIG. 1 may also be sequentially mounted on the substrate 110.

Referring to FIG. 8C, a preliminary encapsulant 150P covering the semiconductor chips 120 and the wires 130 may be formed.

The preliminary encapsulant 150P may be formed by applying and curing a molding material such as, for example, EMC. In this operation, the preliminary encapsulant 150P may be formed so that an upper surface thereof is positioned at a higher level than a level of upper surfaces of the semiconductor chips 120.

Referring to FIG. 8D, a portion of the preliminary encapsulant 150P may be removed to form an encapsulant 150, and external connection bumps 118 may be formed.

The encapsulant 150 may be formed by performing a planarization process, such as a grinding process or a Chemical Mechanical Polishing (CMP) process, on the preliminary encapsulant 150P. The upper surfaces of the semiconductor chips 120 may be exposed through the encapsulant 150, and the upper surface of the encapsulant 150 may be coplanar with the upper surfaces of the semiconductor chips 120. Since the wires 130 extend from the sides of the semiconductor chips 120 and are connected to the substrate 110, a defect in which the wires 130 are exposed and damaged during the planarization process may not occur, and the planarization process may be easily performed.

External connection bumps 118 may be formed on the lower surface of the substrate 110 and may be formed to be connected to the lower pads 116.

Referring to FIG. 8E, a sawing process may be performed to separate the unit semiconductor packages from each other.

The unit semiconductor packages may respectively include unit substrate areas US of the substrate 110. The sawing process may be performed using a blade and/or a laser. During the above-described sawing process, portions of the encapsulant 150 and the substrate 110 may be removed between the semiconductor chips 120 (e.g., the second semiconductor chip 120b and the fourth semiconductor chip 120d) that are adjacent to each other, and form different semiconductor packages. Accordingly, in each of the unit semiconductor packages, the side surfaces of the semiconductor chips 120 may be exposed. Each of the unit semiconductor packages may correspond to the semiconductor package 100 of FIGS. 1 to 2B.

As set forth above, a semiconductor package including a plurality of semiconductor chips and having improved heat dissipation characteristics may be provided by including an encapsulant exposing at least two surfaces of each of a plurality of semiconductor chips.

While non-limiting example embodiments have been described above with reference to the accompanying drawings, it will be apparent to those skilled in the art that modifications and variations could be made without departing from the spirit and scope of the present disclosure.

What is claimed is:

1. A semiconductor package comprising:
a substrate;
four semiconductor chips spaced apart from each other on the substrate, each of the four semiconductor chips comprising an active surface that is perpendicular to an upper surface of the substrate;
wires extending from the active surface of each of the four semiconductor chips, respectively, and electrically connecting the four semiconductor chips and the substrate; and
an encapsulant on the substrate and surrounding the four semiconductor chips,
wherein upper surfaces and first side surfaces of each of the four semiconductor chips are exposed from the encapsulant.

2. The semiconductor package of claim 1, wherein side surfaces of the encapsulant are coplanar with the first side surfaces of the four semiconductor chips, respectively.

3. The semiconductor package of claim 1, wherein, in a plan view, an upper surface of the encapsulant and the upper surfaces of the four semiconductor chips together define a shape of a quadrangle, and
wherein the four semiconductor chips define portions of respective sides of the quadrangle at centers of the respective sides.

4. The semiconductor package of claim 1, wherein upper ends of the wires are at a lower level than a level of the upper surfaces of the four semiconductor chips.

5. The semiconductor package of claim 1, wherein the active surface of each of the four semiconductor chips is a second side surface opposite to a first side surface, from among the first side surfaces, of a same semiconductor chip from among the four semiconductor chips.

6. The semiconductor package of claim 5, wherein the second side surfaces face a center of the substrate.

7. The semiconductor package of claim 1, wherein the substrate comprises upper pads on the upper surface of the substrate, the upper pads connected to the wires in a central region of the substrate that is surrounded by the four semiconductor chips.

8. The semiconductor package of claim 1, wherein the four semiconductor chips comprise:
a first semiconductor chip;
a second semiconductor chip;
a third semiconductor chip that is spaced apart from the first semiconductor chip in a first direction, and faces the first semiconductor chip in the first direction; and
a fourth semiconductor chip that is spaced apart from the second semiconductor chip in a second direction, perpendicular to the first direction, and faces the second semiconductor chip in the second direction.

9. The semiconductor package of claim 8, further comprising a fifth semiconductor chip and a sixth semiconductor chip that are on the substrate and spaced apart from the first semiconductor chip and the third semiconductor chip in the second direction,
wherein the fifth semiconductor chip and the sixth semiconductor chip are spaced apart from each other in the first direction and face each other in the first direction, and
wherein each of the fifth semiconductor chip and the sixth semiconductor chip comprise an upper surface and a side surface that are exposed from the encapsulant.

10. A semiconductor package comprising:
a substrate;
a plurality of semiconductor chip structures horizontally spaced apart from each other on the substrate; and
an encapsulant on the substrate and surrounding the plurality of semiconductor chip structures,
wherein upper surfaces and first side surfaces of each of the plurality of semiconductor chip structures are exposed from the encapsulant, and
wherein the plurality of semiconductor chip structures and the encapsulant define a hexahedral structure on the substrate, and the first side surfaces of the plurality of semiconductor chip structures are portions of sides of the hexahedral structure.

11. The semiconductor package of claim 10, wherein, for each semiconductor chip structure among the plurality of semiconductor chip structures, the semiconductor chip structure further comprises a second side surface that is opposite to a respective first side surface, from among the first side surfaces, of the semiconductor chip structure, and
wherein the semiconductor package further comprises wires extending from the second side surface of the plurality of semiconductor chip structures, respectively, and electrically connecting the plurality of semiconductor chip structures and the substrate.

12. The semiconductor package of claim 11, wherein the second side surface of each of the plurality of semiconductor chip structures is an active surface, wherein at least one connection pad is on the active surface.

13. The semiconductor package of claim 10, further comprising connection bumps on lower surfaces of the plurality of semiconductor chip structures, the connection bumps connecting the plurality of semiconductor chip structures and the substrate.

14. The semiconductor package of claim 10, wherein each of the plurality of semiconductor chip structures comprises a semiconductor chip and a spacer on an upper surface of the semiconductor chip, and
wherein an upper surface of the spacer is exposed from the encapsulant.

15. The semiconductor package of claim 14, wherein the spacer has a smaller area on a plane than an area of the semiconductor chip on the plane, and a portion of the upper surface of the semiconductor chip is exposed from the spacer.

16. The semiconductor package of claim 15, further comprising at least one wire extending from the portion of the upper surface of the semiconductor chip that is exposed, and the at least one wire connects the semiconductor chip and the substrate.

17. The semiconductor package of claim 10, wherein each of the plurality of semiconductor chip structures comprises a lower semiconductor chip and an upper semiconductor chip on an upper surface of the lower semiconductor chip,
wherein the semiconductor package further comprises at least one wire electrically connecting the lower semiconductor chip and the upper semiconductor chip to the substrate, and
wherein the at least one wire is connected to a second side surface of the lower semiconductor chip and a third side surface of the upper semiconductor chip, and the second side surface of the lower semiconductor chip and the third side surface of the upper semiconductor chip face different directions.

18. A semiconductor package comprising:
a substrate;
four semiconductor chips horizontally spaced apart from each other on the substrate; and
an encapsulant on the substrate and surrounding the four semiconductor chips, and exposing two or more surfaces of each of the four semiconductor chips,
wherein at least one surface of each of the four semiconductor chips is a portion of a side surface of the semiconductor package.

19. The semiconductor package of claim 18, wherein each of the four semiconductor chips comprises an upper surface and a side surface that are exposed from the encapsulant.

20. The semiconductor package of claim 18, wherein each of the four semiconductor chips comprises a dynamic random access memory (DRAM) element or a NAND element.
